(19) United States
(12) Patent Application Publication
(10) Pub. No.: US 2025/0346029 A1
(43) Pub. Date: Nov. 13, 2025

(54) INKJET PRINTING APPARATUS FOR DISPLAY AND AN ALIGNING METHOD THEREOF

(71) Applicant: Samsung Display Co., LTD., Yongin-si (KR)

(72) Inventor: EUNSEOK KIM, Yongin-si (KR)

(21) Appl. No.: 19/022,021

(22) Filed: Jan. 15, 2025

(30) Foreign Application Priority Data
May 10, 2024 (KR) 10-2024-0062099

(51) Int. Cl. B41J 2/045; B41J 11/00; B41M 5/00; H10K 71/10; H10K 71/13

(52) U.S. Cl. CPC B41J 2/04505; B41J 2/04581; B41J 11/008; B41M 5/0047; B41M 5/007; H10K 71/135; H10K 71/191

(57) ABSTRACT

An aligning method of an inkjet printing apparatus that prints a glass substrate with a plurality of cells arranged in a matrix form includes a first global key formed at a first position, and a plurality of cell keys formed around each of the plurality of cells. The aligning method further includes calculating the coordinates of each of the plurality of cell keys with the first global key as a reference based on the measurements of the plurality of cell keys and the first global key and reflecting the coordinates of the calculated cell key in the design pattern image to generate a corrected pattern image.

This application claims priority to Korean Patent Application No. 10-2024-0062099, filed on May 10, 2024, and all the benefits accruing therefrom under 35 U.S.C. § 119, the content of which in its entirety is herein incorporated by reference.

### BACKGROUND

### 1. Field

The present invention relates to an inkjet printing apparatus for a display device and an aligning method thereof.

### 2. Description of the Related Art

An inkjet printing technology is a technology that applies an ink to an object by discharging the ink in a form of droplets through a nozzle of an inkjet head and then dispensing the ink to the object.

Recently, inkjet printing technology has been used as a technology to apply organic light emitting materials to glass substrates such as organic light emitting display devices (OLED), or to print a conductive ink, and has also been used as a technology to form a film to protect the deposited material, and to form a film to protect materials deposited on a substrate.

In forming a predetermined thin-film pattern, a passivation layer, etc. is disposed on the organic light emitting display device by using the inkjet printing technology. In order to improve productivity and mass production, an inkjet printing apparatus may be equipped with a multi-head module with a plurality of inkjet heads.

In the process of using the inkjet printing equipment, droplets need be discharged at correct positions to form the desired pattern.

### SUMMARY

An embodiment relates to an inkjet printing apparatus and an alignment method thereof for display devices that can address changes over time in the measuring instruments due to the long-term thermal effects and accurately align the nozzle position of the head and the position of the pixel.

In an embodiment, an aligning method of an inkjet printing apparatus is an aligning method of an inkjet printing apparatus for printing on a glass substrate with a plurality of cells arranged in a matrix form.

In an embodiment, the glass substrate includes a first global key formed at a first position and a plurality of cell keys formed around each of the plurality of cells.

In an embodiment, the aligning method of the inkjet printing apparatus may include calculating the coordinates of each cell key with the first global key as a reference based on the measurements of the plurality of cell keys and the first global key and reflecting the coordinates of the calculated cell keys in the design pattern image to generate a corrected pattern image.

In an embodiment, the calculating the coordinates of each cell key may include measuring a camera start measurement key of each corresponding cell with a plurality of cell cameras, measuring the plurality of cell keys provided in each cell at high speed while moving the glass substrate in a first direction or a second direction that intersects the first direction, and then calculating the relative coordinates of other cell keys using each camera start measurement key as a reference, and measuring the first global key using a head camera and then calculating the coordinates of each cell key using the first global key as a reference.

In an embodiment, the reflecting the coordinates of the calculated cell key may include deriving an offset correction value, which is a difference value of the coordinates of the calculated camera start measurement key and each camera start measurement key based on a designed value, and reflecting the derived offset correction value in the design pattern image to generate the corrected pattern image.

In an embodiment, the first global key may be marked in an upper left corner of the glass substrate.

In an embodiment, the camera start measurement key may be an upper left cell key marked in the upper left corner of the cell in a first row.

In an embodiment, a plurality of global keys may be formed near the upper left, lower left, upper right, and lower right corners of the glass substrate, where the aligning method of the inkjet printing apparatus may further include calculating an error of a substrate traveling axis based on the position values of the global keys measured by one or more cell cameras among the plurality of cell cameras, calculating an error of a head traveling axis based on the position value of the recognized global keys measured by the head camera and performing a camera start position offset correction based on the error of the calculated substrate traveling axis and the error of the calculated head traveling axis.

In an embodiment, the first direction may be a Y-axis direction and the second direction may be an X-axis direction, wherein calculating the error of the substrate traveling axis may include measuring global keys provided on the left and global keys provided on the right, respectively, using two or more cell cameras, and calculating the error of the substrate traveling axis based on the average of the X coordinate difference value of the global keys provided on the left and the X coordinate difference value of the global keys provided on the right.

In an embodiment, the calculating the error of the head traveling axis may include measuring the global keys provided on the left and the global keys provided on the right using two or more head cameras, and calculating the error of the head traveling axis based on the average of the Y coordinate difference values of the global keys provided on the left and the Y coordinate difference values of the global keys provided on the right.

In an embodiment, the calculating the error of the substrate traveling axis may be performed on all glass substrates mounted on the stage, wherein the calculating the error of the head traveling axis may be performed intermittently on the glass substrate mounted on the stage.

In an embodiment, the method may further include, in a state for additionally measuring the first global key by the head camera and aligning the head and the glass substrate, verifying whether a head reference nozzle is in a correct position at a pixel at a certain distance from the first global key.

In an embodiment, the verifying may include, in a state for aligning the head and the glass substrate by measuring the first global key with the head camera, performing a printing by dropping droplets from the head reference nozzle onto a target pixel, determining a printing start position by using the head camera to verify whether the droplets discharged from the head reference nozzle are positioned accurately at the target pixel.

In an embodiment, when the droplets discharged from the head reference nozzle do not fall exactly on the target pixel, the method may further include performing a correction for the printing start position.

In an embodiment, the verifying may be performed intermittently on the glass substrate mounted on the stage.

In an embodiment, an inkjet printing apparatus prints a glass substrate with a plurality of cells arranged in a matrix form.

In an embodiment, a plurality of global keys including a first global key are formed around a corner of the glass substrate, and a plurality of cell keys are formed around each cell.

In an embodiment, the inkjet printing apparatus may include a head unit including a multi-head module with a plurality of inkjet heads and one or more head cameras installed, and a head traveling gantry providing a movement path in an X-axis direction of the multi-head module, a stage transporting the glass substrate along a Y-axis direction and fixing the glass substrate with a vacuum chuck, a mobile cell camera unit including a plurality of cell cameras that measures a cell key formed around each cell, and a camera traveling gantry that provides a movement path in an X-axis direction of the plurality of cell cameras and a printing position setting controller calculating an error of a head traveling axis based on position values of global keys measured by a head camera, and calculating an error of a substrate traveling axis based on position values of the cell keys measured by the plurality of cell cameras.

In an embodiment, the printing position setting controller may calculate the coordinates of each cell key by using the first global key as a reference based on the plurality of cell keys measured by the plurality of cell cameras and the position value of the first global key, and reflecting the coordinates of the calculated cell key in a design pattern image to generate a corrected pattern image.

In an embodiment, the printing position setting controller may derive an offset correction value that is a difference value of the coordinates of the camera start measurement key of the corresponding cells measured by the cell camera and each camera start measurement key based on a designed value, and may reflect the derived offset correction value in the design pattern image to generate the corrected pattern image.

In an embodiment, a plurality of global keys may be formed near the upper left, lower left, upper right, and lower right corners of the glass substrate, respectively, and the printing position setting controller may calculate the error of the substrate traveling axis based on the position values of the global keys measured by one or more cell cameras among the plurality of cell cameras, calculate the error of the head traveling axis based on the position values of the recognized global keys measured by the head camera, and perform a camera start position offset correction based on the error of the calculated substrate traveling axis and the error of the calculated head traveling axis.

In an embodiment, the printing position setting controller may determine whether the head reference nozzle is in the correct position in a pixel at a certain distance from the first global key in a state for aligning the head and the glass substrate by additionally measuring the first global key with the head camera.

According to an embodiment, by generating the coordinates of other cell keys with respect to the reference global key based on the actual measurement of the plurality of cell keys and global keys, and by comparing them with the designed value to derive the offset correction value of the printing start position to correct the design pattern image, the droplets may be discharged at the correct pixel position even in situations where the plurality of alignment keys formed on the substrate are slightly different from one substrate to another due to thermal changes or manufacturing errors.

In an embodiment, fixed density printing may be performed by calculating the optimal rotation angle based on the substrate traveling axis error and the head traveling axis error, and performing the start position offset correction.

### BRIEF DESCRIPTION OF THE DRAWINGS

FIG. 1 is a schematic diagram of a multi-head inkjet printing apparatus, according to an embodiment.

FIG. 2 is a view showing a glass substrate in detail, according to an embodiment.

FIG. 3 is a flowchart showing an alignment method of an inkjet printing apparatus of a display device, according to an embodiment.

FIG. 4 is a view showing a sequence for a high-speed measurement of cell keys provided around a cell with a plurality of cell cameras, according to an embodiment.

FIG. 5 is a view showing a method for calculating the substrate traveling axis error and head traveling axis error, according to an embodiment.

FIG. 6 is a graphical image showing a method to determine a printing start position, according to an embodiment.

FIG. 7 is a view showing an example of a block diagram of a computer device, according to an embodiment.

### DETAILED DESCRIPTION

Hereinafter, the invention will be described more fully with reference to the accompanying drawings, in which embodiments of the invention are shown. As those skilled in the art would realize, the described embodiments may be modified in various different ways, all without departing from the spirit or scope of the invention.

Parts irrelevant to the description will be omitted to clearly describe the invention, and same elements will be designated by same reference numerals throughout the specification.

In addition, the size and thickness of each configuration shown in the drawings are arbitrarily shown for understanding and ease of description, but the present invention is not limited thereto. In the drawings, the thickness of layers, films, panels, regions, etc., is exaggerated for clarity. In the drawings, for understanding and ease of description, the thickness of some layers and areas is exaggerated.

It should be understood that when an element such as a layer, film, region, or substrate is referred to as being “on” another element, it can be disposed directly on the other element or on intervening elements that may also be present. In contrast, when an element is referred to as being “directly on” another element, there are no intervening elements present. Further, in the specification, the word “on” or “above” means positioned on or below the object portion and does not necessarily mean positioned on the upper side of the object portion based on a gravitational direction.

In addition, unless explicitly stated to the contrary, the word “comprise,” and variations such as “comprises” or “comprising,” should be understood to imply the inclusion of stated elements but not the exclusion of any other elements.

In the description, terms such as “ . . . unit”, “ . . . er/or”, “ . . . module”, and the like refer to units that process at least one function or operation, which may be implemented with hardware, software or a combination thereof.

In the present specification, “transmission” or “provision” may include indirect transmission or provision via another device or by use of a bypass in addition to direct transmission or provision.

In the present specification, an expression recited in the singular may be construed as singular or plural unless the expression “one,” “single,” etc., is used.

In conventional inkjet printing equipment, a technology is adopted to perform the alignment of the substrate by checking the plurality of alignment keys formed on the substrate by using a fixed camera installed on the stage, and then performing the printing at a certain distance from the printing position. However, when introducing this printing technology into the inkjet printing apparatus of the multi-head module, the inside of the environmental chamber is heated during the inkjet printing. Accordingly, the absolute position of the fixed camera thermally drifts over time (several um thermal drift per hour). In addition, since the position of the head changes with time due to heat generation from the multi-head module or due to thermal changes caused by the head movement, it becomes difficult to calculate an exact teaching position (the position at which the droplets are discharged from the nozzle corresponding to the pixel). In particularly, in a case of ultra-high-resolution precision inkjet equipment, changes in the position of the fixed camera and the head due to temperature changes causes errors between the pixel positions of the printing head nozzle that discharges the droplets and the glass substrate, making it impossible to perform precise printing.

In addition, the plurality of alignment keys formed on the substrate may have slightly different positions for each substrate, and alignment is performed without taking this into account, so it becomes difficult to be applied in high-precision systems.

Hereinafter, various embodiments of the invention are described in detail with reference to drawings.

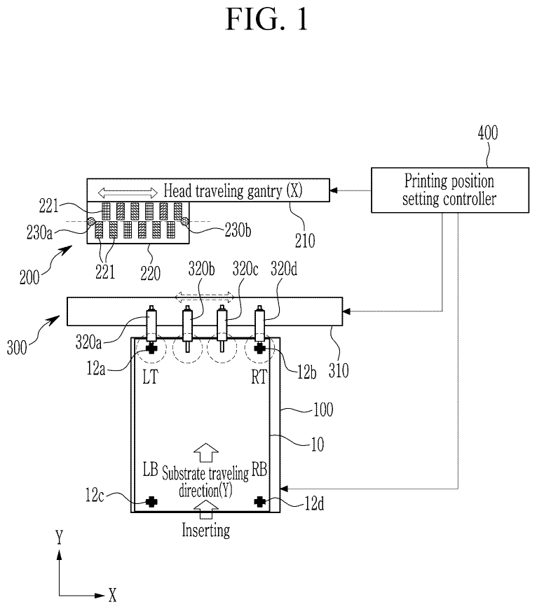

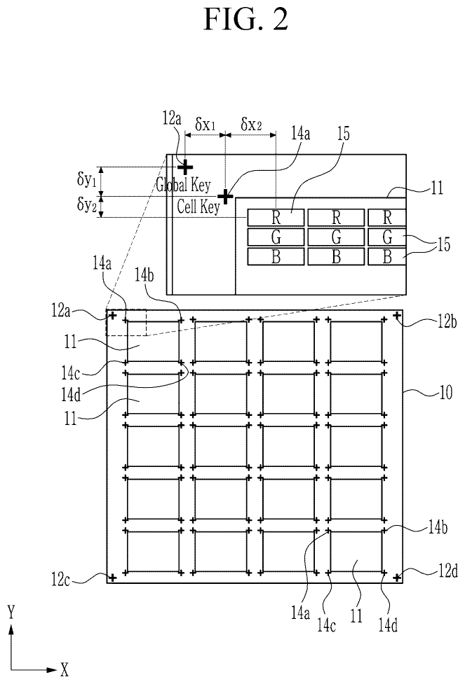

First, an alignment system of a multi-head inkjet printing apparatus will be described below with reference to FIG. 1 and FIG. 2, according to an embodiment.

FIG. 1 is a schematic diagram of a multi-head inkjet printing apparatus, according to an embodiment. FIG. 2 is a detailed drawing showing a glass substrate 10, according to an embodiment.

According to an embodiment, a multi-head inkjet printing apparatus may be used to form a thin-film pattern made of various organic materials including a light emitting layer in an organic light emitting display device, or to form a color filter pattern and an alignment layer pattern in a liquid crystal display.

In an embodiment and referring to FIG. 1, the multi-head inkjet printing apparatus includes a head unit 200 moving along an X-axis to print pixels on a glass substrate 10, a stage 100 transporting the glass substrate 10 along a Y-axis by an air-floating manner and fixing it with a vacuum chuck, a mobile cell camera unit 300 and a printing position setting controller 400.

In an embodiment, the head unit 200 includes a multi-head module 220 in which a plurality of inkjet heads 221 and one or more head cameras 230a and 230b are installed, and a head traveling gantry 210 that provides a movement path for the multi-head module 220. The multi-head module 220 may be attached to and detached from the head traveling gantry 210 and may move in the X-axis direction while attached to the head traveling gantry 210 by a driver (not shown).

In an embodiment, the inkjet head 221 may be configured to be heated at a high temperature above room temperature, and the entire multi-head module 220 may move in the X-axis direction and then operate the stage 100 in a stopped state to print while reciprocating the glass substrate 10 in the Y-axis direction. At this time, the plurality of inkjet heads 221 installed on the multi-head module 220 may print while discharging the ink onto the glass substrate 10, which travels back and forth in the Y-axis direction once or multiple times.

In an embodiment, the bottom of the inkjet head 221 may be equipped with a plurality of nozzles (not shown) that may discharge droplets onto the glass substrate 10. For example, according to an embodiment, the inkjet head 221 may be provided with about 128 or about 256 nozzles, but the invention is not limited to this and may be provided with a various number of nozzles depending on design needs. The nozzles may be arranged at a regular interval and may be equipped to discharge the droplets in the amount of a pl (picoliter) unit.

In an embodiment, each nozzle of the inkjet head 221 may be equipped with a piezoelectric element (not shown), and droplets may be discharged onto the glass substrate 10 through the nozzle by the operation of the piezoelectric element. At this time, the amount of the droplets discharged from the nozzle may be independently adjusted by controlling the voltage applied to the piezoelectric elements.

In an embodiment, the head traveling gantry 210 provides an X-axis travel path along which the plurality of inkjet heads 221 of the multi-head module 220 simultaneously move and may discharge the droplets toward the glass substrate 10 positioned below by using the inkjet head 221 placed on the head traveling gantry 210.

In an embodiment, the head cameras 230a and 230b measure global keys 12a, 12b, 12c, and 12d formed at the corners of the glass substrate 10 and provide the results to the printing position setting controller 400. The printing position setting controller 400 calculates the error of the head traveling axis based on the position value of the global key measured by the head cameras 230a and 230b. According to an embodiment, in order to quickly calculate the error of the head traveling axis, the multiple head cameras have recognized the corresponding global keys, but the invention is not limited to this and, in another embodiment, one head camera may be used to recognize all global keys and calculate the error of the head traveling axis.

In an embodiment, the inkjet printing apparatus may include an environmental chamber (not shown) which may provide a space where the process of discharging the droplets onto the glass substrate 10 is performed.

In an embodiment, the environmental chamber may be provided with the stage 100 where the glass substrate 10 is placed on the stage and transferred, wherein the glass substrate 10 may be transferred by the air floating member provided on the stage 100.

In an embodiment, the mobile cell camera unit 300 includes a plurality of cell cameras 320a, 320b, 320c, and 320d that measure cell keys 14a, 14b, 14c, and 14d formed around the cell, respectively, where a camera traveling gantry 310 provides the movement path in the X direction of the plurality of cell cameras. The plurality of cell cameras 320a, 320b, 320c, and 320d may be installed on the camera traveling gantry 310 by corresponding to the spacing of the plurality of cells formed on the glass substrate 10 and may be moved in the X-axis direction while attached to the camera traveling gantry 310 by a driver (not shown).

In an embodiment, the plurality of cell cameras 320a, 320b, 320c, and 320d may measure the cell keys 14a, 14b, 14c, and 14d formed around the cell, respectively, and may provide the results to the printing position setting controller 400. The printing position setting controller 400 calculates relative coordinates with a reference cell key 0, 0 as the reference based on the position value of the cell key measured by the plurality of cell cameras 320a, 320b, 320c, and 320d. Additionally, some cell cameras (e.g., cell cameras 320a, 320d) may recognize the global keys 12a, 12b, 12c, 12d formed around the glass substrate and may provide the results to the printing position setting controller 400. The printing position setting controller 400 calculates the error of the substrate traveling axis based on the position value of the global key recognized by the cell cameras 320a and 320d.

In an embodiment and referring to FIG. 2, the glass substrate 10 includes a plurality of cells 11 arranged in the form of an MXN matrix, and may include a plurality of global keys 12a, 12b, 12c, 12d provided at the edges of each glass substrate 10. The plurality of global keys may include an upper left global key 12a marked on the upper left corner of the glass substrate 10, an upper right global key 12b marked on the upper right corner, and a lower left global key 12c marked on the lower left corner of the substrate 10, and a lower right global key 12d marked on the lower right corner. According to an embodiment, the upper left global key 12a marked on the upper left corner of the substrate 10 may serve as a reference global key.

In an embodiment and referring to FIG. 2, the glass substrate 10 may include a plurality of cell keys 14a, 14b, 14c, and 14d provided around each cell 11. The plurality of global keys provided in each cell 11 may include an upper left cell key 14a marked on the upper left corner of each cell 11, an upper right cell key 14b marked on the upper right corner, a lower left cell key 14c marked on the lower left corner of the cell 11, and a lower right cell key 14d marked on the lower right corner. According to an embodiment, the upper left cell key 14a each marked on the upper left corner of each cell in the first row of the glass substrate 10, may serve as a start measurement key for the corresponding cell camera.

In an embodiment and referring to FIG. 2, the distance (the position) of the start measurement key 14a of each cell for the reference global key 12a and the distance (the position) between the start measurement key 14a of each cell and the actual pixel 15 are preset by design. For example, for the reference global key 12a, the start measurement key 14a provided in the cell 11 of the first row and the first column is predesigned to be positioned at a distance of δ_{X1} in the X-axis direction and at a distance of δ_{Y1} in the Y-axis direction. Additionally, for the start measurement key 14a, the center of the pixel R of the first row and the first column is predesigned to be positioned at a distance of δ_{X2} in the X-axis direction and at a distance of δ_{Y2} in the Y-axis direction. Therefore, the position of each pixel centered on the reference global key 12a may be known in advance by a design value. And based on these design values, a design pattern image to be printed (i.e., information on the discharge amount of the droplets for each pixel) may be created and the printing is performed. However, because the plurality of alignment keys (the global keys or the reference keys) formed on the substrate may have slightly different positions for each substrate due to thermal changes or manufacturing errors, etc., if the printing is performed based only on the design pattern image, the droplets may not be discharged at the correct position.

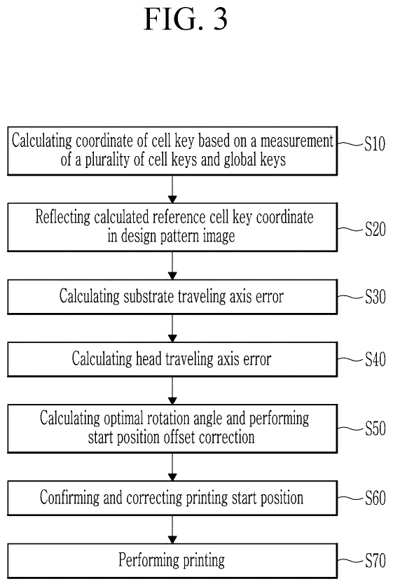

The alignment and the printing method of the inkjet printing apparatus of the display device, according to an embodiment, are described with reference to FIG. 3 to FIG. 6.

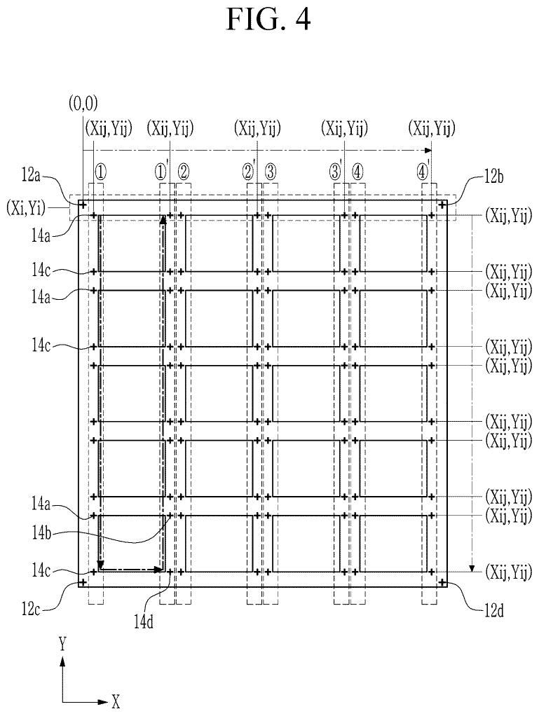

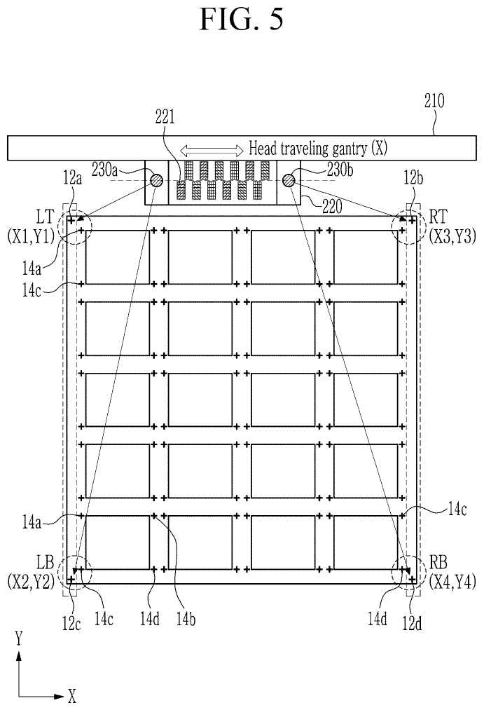

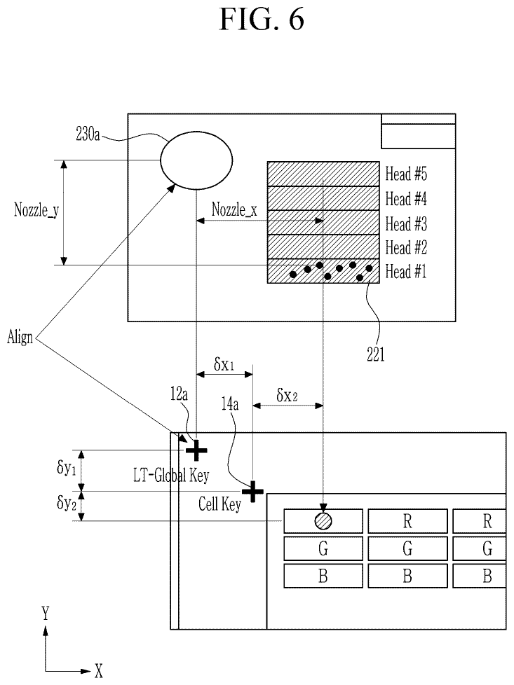

FIG. 3 is a flowchart showing an alignment method of an inkjet printing apparatus of a display device, according to an embodiment. FIG. 4 is a view showing a sequence of a high-speed measurement of cell keys provided around a cell with a plurality of cell cameras, according to an embodiment. FIG. 5 is a view showing a method for calculating the substrate traveling axis error and head traveling axis error, according to an embodiment. FIG. 6 is a view showing a method to determine a printing start position, according to an embodiment.

In an embodiment, the aligning method of the inkjet printing apparatus described below is performed in the printing position setting controller 400 of FIG. 1.

In an embodiment and referring to FIG. 3, first, a coordinate of each cell key is calculated as a global key reference based on a high-speed measurement of a plurality of cell keys and global keys (S10).

Specifically, in an embodiment, the plurality of cell cameras 320a, 320b, 320c, and 320d measure the camera start measurement key (i.e., the upper left cell key 14a marked on the upper left corner of the cell in the first row) of each corresponding cell, and then the glass substrate 10 mounted on the stage 100 is moved in the upper direction of the Y-axis to measure the lower left cell key 14c marked on the lower left corner of each cell in the first row. Afterwards, the glass substrate mounted on the stage is sequentially moved at high speed in the upward direction of the Y-axis while sequentially measuring the upper left cell key 14a and the lower left cell key 14c of the cells from the second row to the last row. After measuring the lower left cell key 14c provided in the lower left corner of the cell in the last row, the plurality of cell cameras 320a, 320b, 320c, and 320d installed on the camera traveling gantry 310 are moved in the X-axis direction and the lower right cell key 14d marked on the lower right corner of the cell in the last row is measured. Then, while sequentially moving the glass substrate 10 mounted on the stage 100 at high speed in the downward direction of the Y-axis, the upper right cell key 14b provided in the upper right corner of the cell and the lower right cell key 14d provided in the lower right corner of the cell are sequentially measured from the last row to the first row. In FIG. 4, a bold one-dot line indicates a cell key measurement order recognized by the plurality of cell cameras, where \textcircled{1}, \textcircled{2}, \textcircled{3}, and \textcircled{4} indicate that the cell cameras 320a, 320b, 320c, and 320d measure the corresponding left cell key, respectively, and \textcircled{1}′, \textcircled{2}′, \textcircled{3}′, and \textcircled{4}′ indicate that the cell cameras 320a, 320b, 320c, and 320d measure the corresponding right cell key, respectively.

In an embodiment, after sequentially measuring all of the cell keys provided around the cell at high speed with the plurality of cell cameras 320a, 320b, 320c, and 320d, by using each camera start measurement key (the upper left cell key marked on the upper left corner of each cell in the first row) as a reference, the relative distance to other cell keys is calculated. In other words, the relative coordinates of other cell keys are obtained using the camera start measurement key as a reference (0, 0).

Afterwards, in an embodiment, the reference global key 12a is measured using the head camera (e.g., 230a) installed on the multi-head module 220 to calculate the distances of all of the cell keys in the glass substrate for one reference global key 12a. In other words, the coordinates of other cell keys are obtained with reference global key 12a as an origin (0, 0).

Next, in an embodiment, the cell key coordinates calculated in the step S10 are reflected in a design pattern image to generate a corrected pattern image (S20). Specifically, an offset correction value is derived, where the offset correction value is the difference value between the coordinates of the camera measurement key calculated in the step S10, and the respective camera measurement key (printing start position) based on the designed value, is derived. A corrected pattern image is then generated by reflecting the derived offset correction value to the design pattern image.

As described above, according to an embodiment, by generating the coordinates of other cell keys with respect to the reference global key based on the actual measurement of the plurality of cell keys and global keys, and by comparing this with the designed value and deriving the offset correction value of the printing start position (the position of the camera measurement key) to correct the design pattern image, discharging the droplets at the correct pixel position may be possible even in the situations where the plurality of alignment keys formed on the substrate are slightly different in the position for each substrate due to thermal changes or manufacturing errors.

In an embodiment, after the step S10, the error of the substrate traveling axis is calculated based on the position value of the global key recognized by the cell camera (S30). Referring to FIG. 5, two cell cameras (e.g., cameras 320a and 320d), are used to obtain coordinates after high-speed measurement of the left global keys 12a and 12c and the right global keys 12b and 12d, respectively, obtain a difference value (X1) of the X coordinates (X1, X2) of the left global key 12a positioned at the upper and lower parts of the glass substrate 10, respectively, and a difference value ΔX2 of the X coordinates (X3 and X4) of the right global keys 12b and 12d positioned at the upper and lower parts of the glass substrate 10. Afterwards, the substrate traveling axis error Θ1 is calculated using Equation 1 immediately below:

$$Θ 1 = ( Δ X 1 + Δ X 2 ) / 2 , \qquad ( Equation 1 )$$

According to an embodiment, the error calculation of the substrate traveling axis may be performed for every glass substrate mounted on the stage.

According to an embodiment, the substrate traveling axis error Θ1 was calculated based on the average of the difference value ΔX1 of the X coordinate of the left global keys 12a and 12c and the difference value ΔX2 of the X coordinate of the right global keys 12b and 12d, but the invention is not limited thereto and, in another embodiment, the substrate traveling axis error Θ1 may be calculated based on one difference value of the difference value ΔX1 of the X coordinate of the left global keys 12a and 12c or the difference value ΔX2 of the X coordinate of the right global keys 12b and 12d.

In an embodiment, the head traveling axis error is then calculated based on the position value of the global key recognized by the head camera (S40). Specifically, by using two head cameras 230a and 230b, the left global keys 12a and 12c and the right global keys 12b and 12d are measured at high speed, respectively, and then the coordinates are calculated, a difference value ΔY1 of the Y coordinates Y1 and Y3 of the left global keys 12a and 12c positioned at the upper and lower parts of the glass substrate 10 and a difference value ΔY2 of the Y coordinates Y2 and Y4 of the right global keys 12b and 12d positioned at the upper and lower parts of the glass substrate 10 are obtained and then a head traveling axis error Θ2 is calculated by using Equation 2 immediately below:

$$Θ 2 = ( Δ Y 1 + Δ Y 2 ) / 2 , \qquad ( Equation 2 )$$

According to an embodiment, the head traveling axis error Θ2 is calculated based on the average of the difference value ΔY1 of the Y coordinates of the left global keys 12a and 12c and the difference value ΔY2 of the Y coordinates of the right global keys 12b and 12d, but the invention is not limited thereto and the error Θ2 of the head traveling axis may be calculated based on only one difference value of the difference value ΔY1 of the Y coordinates of the left global keys 12a and 12c or the difference value ΔY2 of the Y coordinates of the right global keys 12b and 12d.

According to an embodiment, the error calculation of the head traveling axis may be performed intermittently for the glass substrate mounted on the stage, but the invention is not limited thereto and may be performed for all glass substrates.

In an embodiment, the optimal rotation angle is then calculated based on the substrate traveling axis error Θ1, where the head traveling axis error Θ2 is calculated in the step S30 and the step S40, and the start position offset correction is performed (S50). Specifically, the optimal rotation angle Θ is calculated using the substrate traveling axis error Θ1 and the head traveling axis error Θ2 calculated in the step S30 and the step S40 by applying the Equation 3 immediately below:

$$Θ = ( Θ 1 + Θ 21 ) / 2 , \qquad ( Equation 3 )$$

Next, in an embodiment, the calculated optimal rotation angle Θ is reflected in the position coordinates of each camera start key calculated in the step S10 to perform a camera start position offset correction.

In an embodiment, after the step S50, the global reference key 12a is measured once again with the head camera 230a to confirm and correct the printing start position (S60). This is a step to reflect changes in the printing start position due to changes in the nozzle position, and it does not need to be performed for every substrate and may be performed intermittently. In an embodiment and referring to FIG. 6, after measuring the global reference key 12a once more with the head camera 230a and aligning the head and substrate, it is determined whether to proceed with the printing by determining whether the head reference nozzle is in the correct position on the pixel at a certain distance from global reference key 12a. Specifically, to verify whether the head reference nozzle, located Nozzle_x distance away in the X-axis direction and Nozzle_y distance away in the Y-axis direction from the head camera 230a, is positioned at a pixel that is δ_{X1}+δ_{X2} distance away in the X-axis direction and δ_{Y1}+δ_{Y2} distance away in the Y-axis direction from the global reference key 12a, printing is performed by measuring the global reference key 12a with the head camera 230a, aligning the head and glass substrate, and then dropping droplets from the head reference nozzle onto the pixel.

Next, in an embodiment, the printing start position is determined by verifying whether the droplets discharged from the nozzle are positioned accurately at the corresponding pixel by using the head camera 230a.

In an embodiment, if the droplets discharged from the nozzle do not fall exactly on the corresponding pixel (i.e., if the printing start position changes due to the change in the nozzle position), the printing start position is corrected.

Then, the printing is performed based on the final confirmed printing start position (S70).

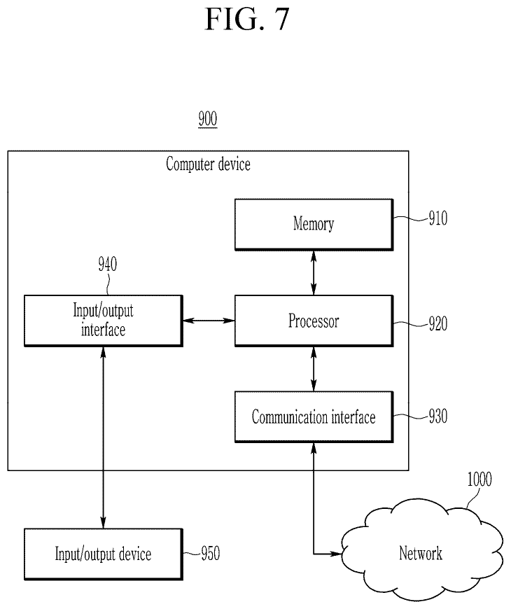

FIG. 7 is a view showing an example of a computer device, according to an embodiment. The printing position setting controller 400 described in FIG. 1 may be realized by a computer device 900 described in FIG. 7.

In an embodiment, the computer device 900, as shown in FIG. 7, may include a memory 910, a processor 920, a communication interface 930, and an input/output interface 940. The memory 910 as a computer-readable recording medium may include a permanent mass storage device such as a random access memory (RAM), a read-only memory (ROM), and a disk drive. Additionally, an operating system and at least one program code may be stored in the memory 910. These software components may be loaded into the memory 910 from a readable recording medium on a computer separate from the memory 910. The recording medium that is readable by the separate computer may include a recording medium that is readable by a computer, such as a hard disk, a flash memory, an optical disk, or an external hard disk. Additionally, these software components may be loaded into the memory 910 through the communication interface 930.

In an embodiment, the processor 920 may be configured to process instructions of a computer program by performing basic arithmetic, logic, and input/output operations. The instructions may be provided to the processor 920 by the memory 910 or the communication interface 930.

In an embodiment, the communication interface 930 may provide a function for the computer device 900 to communicate with other devices through a network 1000.

In an embodiment, the input/output interface 940 may be a means for interfacing with the input/output device 950. For example, the input device may include devices such as a microphone, a keyboard or a mouse, and the output device may include devices such as a display or speakers.

The embodiments described above may be implemented in the form of a computer program that can be executed through various components on a computer, and such a computer program may be recorded in a computer-readable medium. In this case, the medium may include a hardware device specially configured to store and execute program instructions, including a magnetic medium such as a hard disk, a floppy disk, and a magnetic tape, an optical recording medium such as a CD-ROM and a DVD, a magneto-optical medium such as a floptical disk, a ROM, a RAM, and a flash memory, etc.

Moreover, the steps constituting the method of the invention may be performed in an appropriate order unless explicitly stated or contradicted by the order. The invention is not necessarily limited to the order of the steps described above. In the present disclosure, use of all examples or illustrative terms (e.g., a frequency synchronization example) is merely for describing the invention in detail, and thus the scope of the invention is not limited thereto. In addition, a person of ordinary skill in the art could recognize that various modifications, combinations, and changes may be made within the scope of the invention.

While this invention has been described in connection with what is presently considered to be practical embodiments, it should be understood that the invention is not limited to the disclosed embodiments, but, on the contrary, is intended to cover various modifications and equivalent arrangements included within the spirit and scope invention. Moreover, although embodiments have been described in detail above, the scope of the invention is not limited thereto, and various modifications and improvements made by those skilled in the art using the basic concepts of the invention. Therefore, the scope of the invention is not limited to the contents described in the detailed description of the specification. Moreover, the embodiments or parts of the embodiments may be combined in whole or in part without departing from the scope of the invention.

What is claimed is:

1. In an inkjet printing apparatus for printing on a glass substrate with a plurality of cells arranged in a matrix form,
wherein the glass substrate includes a first global key formed at a first position and a plurality of cell keys formed around each cell,
an aligning method of the inkjet printing apparatus comprising:
generating a calculated cell key by calculating coordinates of each of the plurality of cell keys using the first global key as a reference based on measurements of the plurality of cell keys and the first global key; and
reflecting the coordinates of the calculated cell key in a design pattern image to generate a corrected pattern image.

2. The aligning method of the inkjet printing apparatus of claim 1, wherein:
the calculating the coordinates of each of the plurality of cell keys includes,
measuring a camera start measurement key of each corresponding cell with a plurality of cell cameras, measuring the plurality of cell keys provided in each cell at high speed while moving the glass substrate in a first direction or a second direction that intersects the first direction, and then calculating relative coordinates of other cell keys using each camera start measurement key as a reference, and
measuring the first global key using a head camera and then calculating the coordinates of each of the plurality of cell keys using the first global key as a reference.

3. The aligning method of the inkjet printing apparatus of claim 2, wherein:
the reflecting the coordinates of the calculated cell key includes,
deriving an offset correction value, wherein the offset correction value is a difference value of coordinates of the calculated camera start measurement key and each camera start measurement key based on a designed value, and
reflecting the derived offset correction value in the design pattern image to generate the corrected pattern image.

4. The aligning method of the inkjet printing apparatus of claim 2, wherein:
the first global key is marked in an upper left corner of the glass substrate.

5. The aligning method of the inkjet printing apparatus of claim 2, wherein:
the camera start measurement key is an upper left cell key marked in an upper left corner of a cell in a first row.

6. The aligning method of the inkjet printing apparatus of claim 2, wherein:
a plurality of global keys is formed near an upper left, a lower left, an upper right, and a lower right corner of the glass substrate, wherein
the aligning method of the inkjet printing apparatus further includes,
calculating an error of a substrate traveling axis based on position values of the global keys measured by one or more cell cameras among the plurality of cell cameras;
calculating an error of a head traveling axis based on a position value of the recognized global keys measured by the head camera; and
performing a camera start position offset correction based on the error of the calculated substrate traveling axis and the error of the calculated head traveling axis.

7. The aligning method of the inkjet printing apparatus of claim 6, wherein:
the first direction is a Y-axis direction and the second direction is an X-axis direction, and wherein
the calculating the error of the substrate traveling axis includes
measuring global keys provided on a left and global keys provided on a right, using two or more cell cameras, and
calculating the error of the substrate traveling axis based on the average of the X coordinate difference value of the global keys provided on the left and the X coordinate difference value of the global keys provided on the right.

8. The aligning method of the inkjet printing apparatus of claim 7, wherein:
the calculating the error of the head traveling axis includes,
measuring the global keys provided on the left and the global keys provided on the right using two or more head cameras, and
calculating the error of the head traveling axis based on the average of the Y coordinate difference values of the global keys provided on the left and the Y coordinate difference values of the global keys provided on the right.

9. The aligning method of the inkjet printing apparatus of claim 8, wherein:
the calculating the error of the substrate traveling axis is performed on all glass substrates mounted on a stage, and the calculating the error of the head traveling axis is performed intermittently on the glass substrate mounted on the stage.

10. The aligning method of the inkjet printing apparatus of claim 6, further comprising:
in a state for measuring the first global key by the head camera and aligning the head and the glass substrate, verifying whether a head reference nozzle is in a correct position on a pixel at a certain distance from the first global key.

11. The aligning method of the inkjet printing apparatus of claim 10, wherein:
the verifying includes,
in a state for aligning the head and the glass substrate by measuring the first global key with the head camera, performing a printing by dropping droplets from the head reference nozzle onto a target pixel, and
determining a printing start position by using the head camera to verify whether the droplets discharged from the head reference nozzle are positioned accurately at the target pixel.

12. The aligning method of the inkjet printing apparatus of claim 11, further comprising:
when the droplets discharged from the head reference nozzle do not fall exactly on the target pixel, performing a correction for the printing start position.

13. The aligning method of the inkjet printing apparatus of claim 10, wherein:
the verifying is performed intermittently on the glass substrate mounted on the stage.

14. In an inkjet printing apparatus for printing on a glass substrate with a plurality of cells arranged in a matrix form,
a plurality of global keys including a first global key is formed around a corner of the glass substrate, and a plurality of cell keys is formed around each cell,
wherein the inkjet printing apparatus includes,
a head unit including a multi-head module with a plurality of inkjet heads and one or more head cameras installed and a head traveling gantry providing a movement path of the multi-head module in an X-axis direction;
a stage transporting the glass substrate along a Y-axis direction and fixing the glass substrate with a vacuum chuck;
a mobile cell camera unit including a plurality of cell cameras that measures a cell key formed around each cell, and a camera traveling gantry that provides a movement path of the plurality of cell cameras in an X-axis direction; and
a printing position setting controller calculating an error of a head traveling axis based on position values of global keys measured by a head camera, and calculating an error of a substrate traveling axis based on position values of the cell keys measured by the plurality of cell cameras.

15. The inkjet printing apparatus of claim 14, wherein:
the printing position setting controller
calculates the coordinates of each cell key by using the first global key as a reference based on the plurality of cell keys measured by the plurality of cell cameras and the position value of the first global key, and
reflects the coordinates of the calculated cell keys in a design pattern image to generate a corrected pattern image.

16. The inkjet printing apparatus of claim 15, wherein:
the printing position setting controller
derives an offset correction value that is a difference value of the coordinates of the camera start measurement key of the corresponding cells, measured by the cell camera and each camera start measurement key based on a designed value, and
reflects the derived offset correction value in the design pattern image to generate the corrected pattern image.

17. The inkjet printing apparatus of claim 15, wherein:
a plurality of global keys is formed near an upper left, a lower left, an upper right, and a lower right corner of the glass substrate, and
the printing position setting controller
calculates the error of the substrate traveling axis based on the position values of the global keys measured by one or more cell cameras among the plurality of cell cameras,
calculates the error of the head traveling axis based on the position values of the recognized global keys measured by the head camera, and
performs a camera start position offset correction based on an error of the calculated substrate traveling axis and an error of the calculated head traveling axis.

18. The inkjet printing apparatus of claim 15, wherein:
the printing position setting controller verifies whether the head reference nozzle is in the correct position on a pixel at a certain distance from the first global key in a state for aligning the head and the glass substrate by additionally measuring the first global key using the head camera.

19. The inkjet printing apparatus. of claim 14. wherein the stage transports the glass substrate along a Y-axis by an air-floating manner.

20. The inkjet printing apparatus, of claim 14, wherein the multi-head module is configured to be attached to and detached from the head traveling gantry.
